(19) United States
(12) Patent Application Publication
(10) Pub. No.: US 2003/0121698 A1
(43) Pub. Date: Jul. 3, 2003

(54) Semiconductor device and printed wiring board having electrode pads

(75) Inventors: Yoshitaka Kyougoku, Minato-ku (JP); Masahiro Ishibashi, Minato-ku (JP)

Correspondence Address: SUGHRUE MION, PLLC, 2100 PENNSYLVANIA AVENUE, N.W., WASHINGTON, DC, 20037, US

(73) Assignee: NEC CORPORATION

(21) Appl. No.: 10/318,063

(22) Filed: Dec. 13, 2002

(30) Foreign Application Priority Data
Dec. 27, 2001 (JP) 2001-396697

(51) Int. Cl. H05K 1/11

(52) U.S. Cl. 174/261

(57) ABSTRACT

A printed wiring board includes an insulating layer, and an electrode pad and interconnect that is connected to the electrode pad that are provided on the insulating layer. A vacant space is formed in the insulating layer, and of the electrode pad and interconnect, at least a portion of the electrode pad is exposed in the vacant space.

### BACKGROUND OF THE INVENTION

1. Field of the Invention

The present invention relates to a printed wiring board having electrode pads for electrical connections, a semiconductor device, and an interconnection structure that uses these components.

2. Description of the Related Art

FIG. 1 shows a sectional view of one example of a printed wiring board of the prior art. Printed wiring board 1101 shown in FIG. 1 includes insulating layers 1102a-1102c, interconnects 1103a and 1103b formed on the upper surface of uppermost insulating layer 1102a, interconnect 1103c that is formed between two insulating layers 1102a and 1102c, and interconnect 1103d that is formed on the lower surface of lowermost insulating layer 1102c. Interconnect 1103a and interconnect 1103c are electrically connected to each other by way of via-hole 1105. Interconnect 1103b and interconnect 1103d are electrically connected together by way of through-hole 1106. In addition, protective layers 1108a and 1108b composed of insulating materials are provided on the upper surface and lower surface, respectively, of printed wiring board 1101.

Protective layers 1108a and 1108b are formed in a pattern that exposes one end of interconnects 1103a and 1103d. The regions of interconnects 1103a and 1103d that are exposed from protective layers 1108a and 1108b are electrode pads 1104a and 1104b for electrical connection to outside components such as semiconductor elements or semiconductor devices. If connecting parts between interconnects are considered to be electrode pads in the wide sense of the term, the connecting part between interconnect 1103a and interconnect 1103c by way of via-hole 1105 and the connecting part between interconnect 1103b and interconnect 1103d by way of through-hole 1106 can also be referred to as electrode pads.

FIG. 2 shows a sectional view of the principal components for a case in which a semiconductor device has been mounted on the printed wiring board shown in FIG. 1. In FIG. 2, semiconductor device 1110 includes lead terminal 1111 for electrical connection with the outside, and this lead terminal 1111 is electrically connected to electrode pad 1103a of printed wiring board 1101 by means of solder 1112, which is the connection member. A case is here considered in which changes in the ambient temperature or mechanical stress from the outside results in the application of a force in a direction that separates semiconductor device 1110 from printed wiring board 1101. Electrode pad 1103a closely adheres to insulating layer 1102a on its lower surface, and as a result, when force is applied upon semiconductor device 1110 in a direction that separates it from printed wiring board 1101, tensile stress acts on solder 1112, as shown in FIG. 3. The repeated application of this stress to solder 1112 can in some cases generate cracks in solder 1112 and decrease the reliability of the electrical connection between lead terminals 1111 and electrode pads 1103a.

FIG. 4 shows a sectional view of one example of a semiconductor device of the prior art. Semiconductor device 1121 shown in FIG. 4 is referred to as the BGA (Ball Grid Array) type and includes: semiconductor element 1122 that is provided with electrode pad 1124b, electrode pad 1124a that is provided on the lower surface of semiconductor device 1121, solder ball 1123 that is electrically connected to electrode pad 1124a for the purpose of electrically connecting this semiconductor device 1121 to a printed wiring board (not shown in the figure), wire 1125 for electrically connecting electrode pad 1124a and electrode pad 1124b, and encapsulation resin 1126. Encapsulation resin 1126 encapsulates semiconductor element 1122, electrode pad 1124a, and wire 1125. When this type of semiconductor device 1121 is mounted on a printed wiring board, electrode pad 1124a is restrained in its position by encapsulation resin 1126. Thus, changes in the ambient temperature or mechanical stress applied from the outside cause tensile stress or compressive stress to work on solder ball 1123. The repeated application of this stress upon solder ball 1123 may in some cases cause cracks to occur in solder ball 1123, thereby decreasing the reliability of the electrical connection between printed wiring board and electrode pad 1124a that is realized by solder ball 1123.

Various proposals have therefore been made for easing the above-described stress and improving the reliability of electrical connections in printed wiring boards and semiconductor devices of the prior art.

As an example, Japanese Patent Laid-Open No. 2001-77226 discloses a semiconductor device that includes: a flexible wiring board having a semiconductor chip mounted on one side, a rigid wiring board having rigidity, and a connection member for electrically connecting this flexible wiring board and rigid wiring board. In this semiconductor device, the flexible wiring board is arranged such that the semiconductor chip confronts the rigid wiring board. The connection member is a cylindrical piece having sufficient height to form a space between the flexible wiring board and rigid wiring board for accommodating a semiconductor chip and is provided so as to partially support the flexible wiring board with respect to the rigid wiring board in the vicinity of the semiconductor chip. A flexible wiring board on which a semiconductor chip has been mounted is therefore connected to a rigid wiring board in a manner that allows displacement, and stress that acts upon the semiconductor device is therefore alleviated by the flexible wiring board.

The example disclosed in Japanese Patent Laid-Open No. 2001-77226 alleviates stress by means of the flexibility of the flexible wiring board. In contrast, devices have been proposed in which stress is alleviated by means of movable electrode pads. As examples, WO98/32170, Japanese Patent Laid-Open No. 2000-174165, and Japanese Patent Laid-Open No. 2001-118882 disclose constructions in which electrode pads are provided on a resin material having a low elastic modulus such as an elastomer to alleviate stress.

In addition, Japanese Patent Laid-Open No. 65649/1995 discloses an interconnect structure in which an interconnect that is formed over an insulative wiring board is in a partially floating state from the insulative wiring board. This construction alleviates stress that occurs at the interface between the insulative wiring board and interconnect by means of the portion of interconnect that floats above the insulative wiring board, whereby shifting of the position of the interconnect can be prevented.

With the miniaturization and development toward multi-functionality of electronic devices, the pitch of the connection terminals of components is becoming increasingly narrow. These trends are accompanied by a decrease in the area, i.e., connection region area, of the electrode pads of a semiconductor device or printed wiring board. Thus, when a flexible wiring board is partially supported by a connection member as in the construction that is disclosed in Japanese Patent Laid-Open No. 2001-77226, the connection region that is constituted by the connection member decreases. The strength of the connection member therefore also decreases, and an improvement in connection reliability cannot be obtained to the degree that would be expected.

On the other hand, in a construction in which electrode pads are provided on a resin having a low elastic modulus, as disclosed in WO98/32170, Japanese Patent Laid-Open No. 2000-174165, and Japanese Patent Laid-Open No. 2001-118882, the electrode pads are provided in close adhesion to the resin of low elastic modulus, and when stress acts upon the electrode pads, displacement is to some extent restricted by the resin. Further, the elastic modulus of the resin usually indicates simply the elastic modulus at normal temperature, and no consideration is given to the effect of vitrification in which an elastic modulus of from several GPa to several tens of GPa is obtained at cold temperatures. As a result, the connection reliability of the above-described inventions is influenced by the ambient temperature in the case of cold temperatures encountered in use in cold areas or in temperature cycles.

In the device that is described in Japanese Patent Laid-Open No. 65649/1995, a portion of the interconnect is provided so as to float with respect to the insulative wiring board, thereby effectively alleviating stress that acts on the interconnect. However, because the electrode pads are formed in close adhesion to the insulative wiring board, a problem still remains regarding the reliability of the connection members themselves over the electrode pads.

### SUMMARY OF THE INVENTION

It is an object of the present invention to improve the reliability of connection members by reducing the stress that is applied to the connection members, and in turn, to improve the reliability of electrical connections in a connection structure that is realized by way of electrode pads.

The inventors of the present invention, as a result of continued and diligent investigation to achieve the above-described object, have found that allowing displacement of electrode pads according to stress that is applied from the outside alleviates the stress applied to connection members that are on the electrode pads, whereby the reliability of the connection members can be effectively improved even when the area of the electrode pads is small or when changes occur in the ambient temperature. As a structure that allows displacement of electrode pads, one might have considered such structure in which that electrode pads only contact and do not closely adhere to members adjacent to the electrode pads (adjacent parts). Although such a structure might be effective when stress is applied in a direction to separate electrode pads from adjacent parts, it could have no effect when stress is applied to press electrode pads toward adjacent parts. Thus, if the conditions in which products are actually used are considered, there will be cases in which no effect is produced depending on whether the temperature is low or high.

A printed wiring board of the present invention includes an insulating layer, and an electrode pad and interconnect that connects to the electrode pad that are provided on the insulating layer. A vacant space is formed in the insulating layer, and of the electrode pad and interconnect, at least a portion of the electrode pad is exposed in the vacant space.

A semiconductor device of the present invention includes a semiconductor element, encapsulation resin for sealing the semiconductor element, an interconnect that is connected to the semiconductor element, and an electrode pad that connects to this interconnect. A vacant space is formed in the encapsulation resin, and of the electrode pad and interconnect, at least a portion of the electrode pad is exposed in the vacant space.

The present invention is further directed to an electrical connection structure of a component and the above-described printed wiring board, wherein the electrode pads of the printed wiring board are electrode pads that connect to the component, and wherein the electrical connection structure is electrically connected to the component by means of connection members; or also an electrical connection structure of a printed wiring board and the above-described semiconductor device, wherein the electrode pads of the semiconductor device are electrode pads that are connected to the printed wiring board, the printed wiring board includes on its surface electrode pads that are connected to the electrode pads of the semiconductor device, and the electrode pads of the semiconductor device and the electrode pads of the printed wiring board are electrically connected by connection members.

According to the present invention that is constituted as described above, of an electrode pad and an interconnect that is connected to the electrode pad, at least a portion of the electrode pad is exposed in a vacant space, whereby the portion of the electrode pad that is exposed in the vacant space is not restricted by adjacent parts and thus can be freely displaced. As a result, the electrode pad is displaced in accordance with stress that is applied to the connection member that is connected to the electrode pad, thereby alleviating stress that is applied to the connection member and consequently, improving the reliability of the connection member and improving the reliability of the electrical connection in the connection structure that is realized by the electrode pads.

Not only the electrode pad, but in addition, the portion of the interconnect that is close to the electrode pad is also preferably exposed in the vacant space. This configuration increases the degree to which the electrode pad can be displaced and therefore more effectively alleviates the stress that is applied to the connection member. Further, covering the portion of the interconnect that is not exposed in the vacant space with a low elastic member enables displacement of the interconnect even in portions that are covered by the low elastic member. In addition, employing a bent shape for a portion of the interconnect that is covered by the low elastic member or the portion of the interconnect that is exposed in the vacant space enables a still greater range of possible displacement of the electrode pad. Further, the use of a support to support the back surface of a part of the portion that is exposed in the vacant space enables a suppression of excessive deformation of the electrode pad when connecting an electrode pad by means of a connection member.

The above and other objects, features, and advantages of the present invention will become apparent from the following description with reference to the accompanying drawings, which illustrate examples of the present invention.

### BRIEF DESCRIPTION OF THE DRAWINGS

FIG. 1 is a sectional view of a printed wiring board of the prior art.

FIG. 2 is a sectional view of the printed wiring board shown in FIG. 1 with a semiconductor device mounted on the board.

FIG. 3 is a sectional view for explaining a problem associated with the printed wiring board that is shown in FIG. 1.

FIG. 4 is a sectional view of a semiconductor device of the prior art.

FIG. 5 is a perspective view of a printed wiring board according to the first embodiment of the present invention.

FIG. 6 is a sectional view taken along an interconnect of the printed wiring board shown in FIG. 5.

FIG. 7 is an enlarged perspective view of the vicinity of an electrode pad that is exposed on the upper surface of the printed wiring board shown in FIG. 5.

FIG. 8 is a sectional view of the vicinity of an electrode pad when a semiconductor device has been mounted on the printed wiring board that is shown in FIG. 5.

FIG. 9 is a sectional view showing the displacement of an electrode pad for a state in which a semiconductor device is mounted on the printed wiring board that is shown in FIG. 5.

FIG. 10 is a perspective view of a semiconductor device according to the second embodiment of the present invention when mounted on a printed wiring board.

FIG. 11 is a sectional view of the principal parts of FIG. 10.

FIG. 12a and FIG. 12b are sectional views showing the displacement of an electrode pad in the semiconductor device that is shown in FIG. 10.

FIG. 13 is a perspective view of an example of a printed wiring board according to the third embodiment of the present invention.

FIG. 14 is a perspective view of another example of the printed wiring board according to the third embodiment of the present invention.

FIG. 15 is a perspective view of another example of a printed wiring board according to the third embodiment of the present invention.

FIG. 16 is a sectional view of another example of a printed wiring board according to the third embodiment of the present invention.

FIG. 17 is a sectional view of an example of a semiconductor device according to the third embodiment of the present invention.

FIG. 18 is a perspective view of an example of a printed wiring board according to the fourth embodiment of the present invention.

FIG. 19 is a perspective view of another example of a printed wiring board according to the fourth embodiment of the present invention.

FIG. 20 is a perspective view of an example of a printed wiring board according to the fifth embodiment of the present invention.

FIG. 21 is a sectional view taken in the direction of an interconnect in the vicinity of a vacant space of the printed wiring board shown in FIG. 20.

FIG. 22 is a plan view of the vicinity of a vacant space in another example of a printed wiring board according to the fifth embodiment of the present invention.

FIG. 23 is a plan view of the vicinity of a vacant space in further another example of a printed wiring board according to the fifth embodiment of the present invention.

FIG. 24 is a perspective view of another example of a printed wiring board according to the fifth embodiment of the present invention.

FIG. 25 is a sectional view taken in the direction of an interconnect in the vicinity of a vacant space in the printed wiring board shown in FIG. 24.

FIG. 26 is a perspective view of an example of a printed wiring board according to the sixth embodiment of the present invention.

FIG. 27 is a sectional view taken along the direction of an interconnect in the vicinity of a vacant space of the printed wiring board shown in FIG. 26.

FIG. 28 is a perspective view of another example of a printed wiring board according to the sixth embodiment of the present invention.

FIG. 29 is a sectional view taken along the direction of an interconnect in the vicinity of a vacant space of the printed wiring board shown in FIG. 28.

FIG. 30 is a sectional view taken along the direction of an interconnect in the vicinity of a vacant space of an example of the printed wiring board according to the seventh embodiment of the present invention.

FIG. 31 is a sectional view taken along the direction of an interconnect in the vicinity of a vacant space in an example of a printed wiring board according to the eighth embodiment of the present invention.

FIG. 32 is perspective view of another example of a printed wiring board according to the eighth embodiment of the present invention.

FIG. 33 is a sectional view taken along the direction of an interconnect in the vicinity of a vacant space of the printed wiring board shown in FIG. 32.

FIG. 34 is a sectional view taken along the direction of an interconnect in the vicinity of a vacant space of another example of a printed wiring board according to the eighth embodiment of the present invention.

FIG. 35 is a sectional view taken along the direction of an interconnect in the vicinity of a vacant space of another example of a printed wiring board according to the eighth embodiment of the present invention.

FIG. 36 is a sectional view of the vicinity of a vacant space of an example in which several representative constructions of embodiments of the present invention have been applied in a semiconductor device.

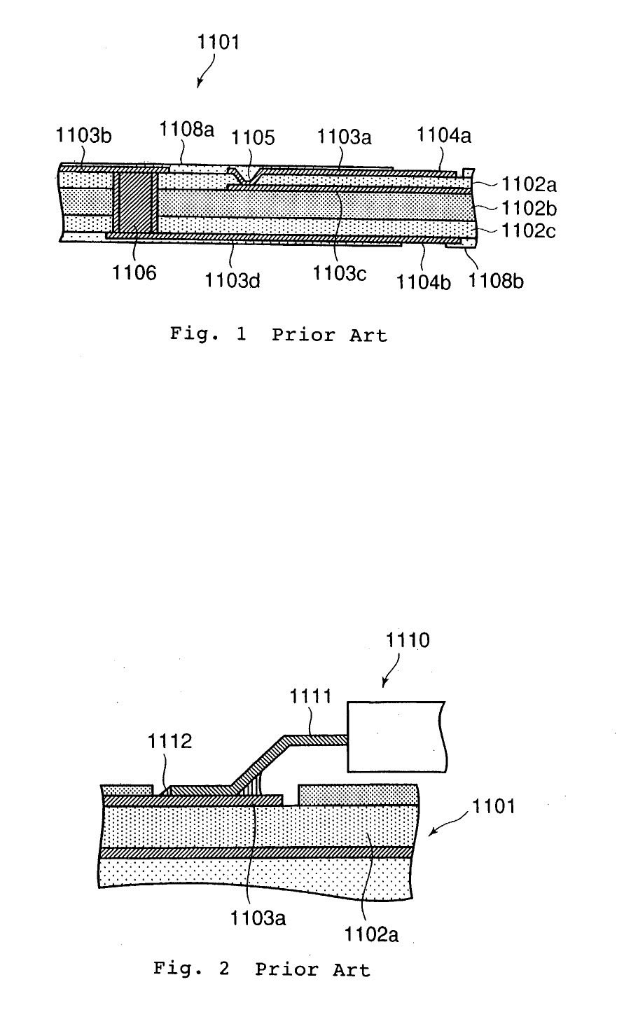

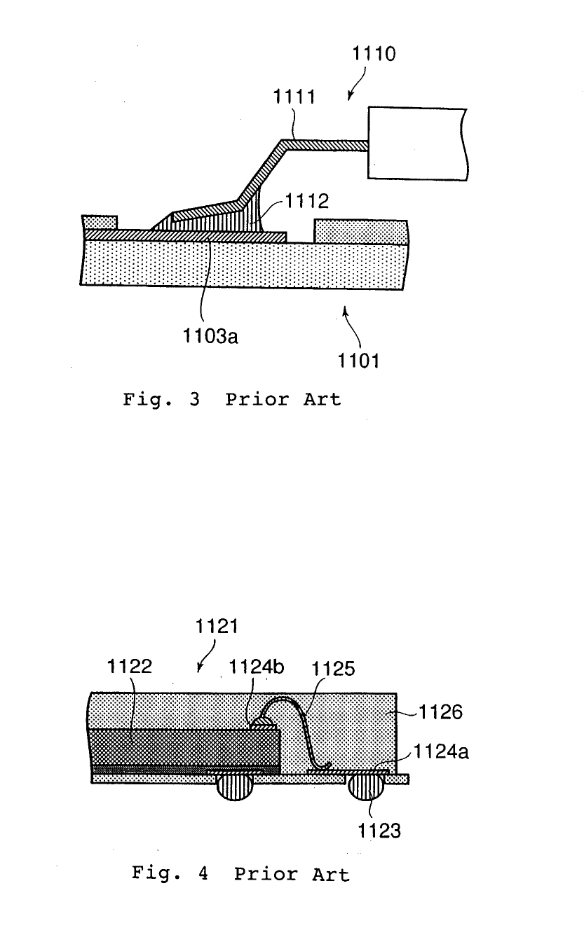

### DETAILED DESCRIPTION OF THE PREFERRED EMBODIMENTS

First Embodiment

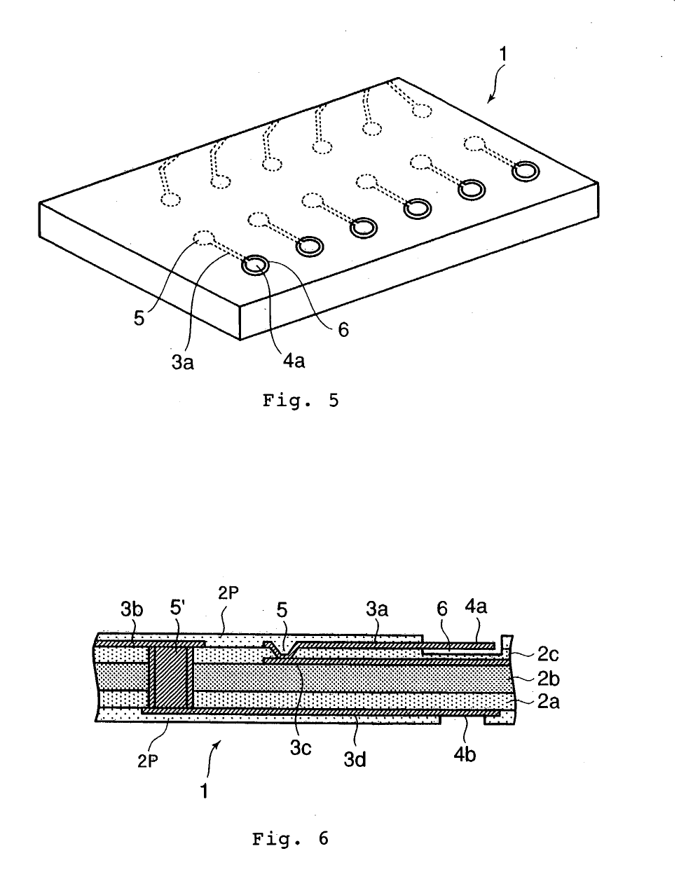

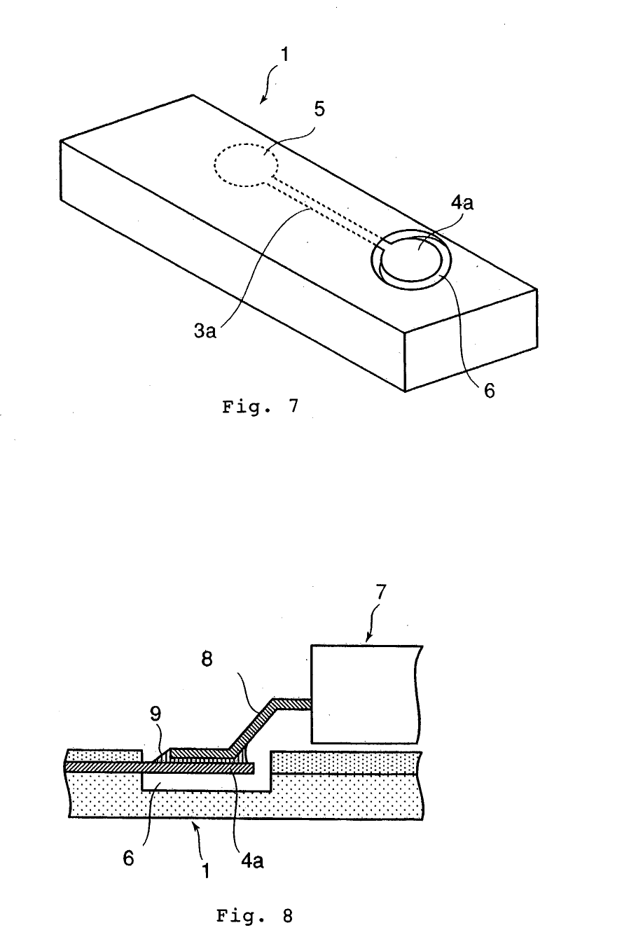

As shown in FIG. 5 to FIG. 7, printed wiring board 1 of the present embodiment includes: insulating layers 2a, 2b, and 2c; interconnect 3a and 3b that are formed on the upper surface of uppermost insulating layer 2c; interconnect 3c that is formed between the two insulating layers 2b and 2c; and interconnect 3d that is formed on the lower surface of lowermost insulating layer 2a. Interconnect 3a and interconnect 3c are electrically connected to each other by way of via-hole 5. Interconnect 3b and interconnect 3d are electrically connected to each other by way of through-hole 5′. Protective layer 2P that is composed of an insulative material is provided respectively on the upper surface and lower surface of printed wiring board 1.

Protective layer 2P is formed in a pattern that exposes one end of each of interconnect 3a and 3d. The portions of interconnects 3a and 3d that are exposed from protective layer 2p are electrode pads 4a and 4b for electrical connection with other components such as a semiconductor elements, semiconductor devices, or chip components (collectively referred to as “surface mounted components”). Although electrode pad 4a is round in shape in the example shown in the figure, the shape need not be round and can be another shape (such as tear-shaped, rectangular, polygonal, spherical, cubic, or polyhedral).

Vacant space 6 is formed in insulating layer 2c by removing a portion of uppermost insulating layer 2c in the area surrounding electrode pad 4a. Electrode pad 4a is supported only by interconnect 3a in cantilever form exposed in this vacant space 6.

FIG. 8 is a sectional view showing the vicinity of electrode pad 4a for a case in which semiconductor device 7 is mounted as a component on above-described printed wiring board 1. As shown in FIG. 8, semiconductor device 7 includes lead terminal 8 for electrical connection with the outside, this lead terminal 8 being connected with electrode pad 4a by solder 9, which is the connection member. When stress acts to produce relative displacement between printed wiring board 1 and semiconductor device 7 under these circumstances, tensile stress or compressive stress is applied to solder 9 that connects printed wiring board 1 and semiconductor device 7. In this case, electrode pad 4a is supported in vacant space 6 as previously described, and, not being restricted by insulating layer 2c, i.e., an adjacent part, electrode pad 4a is deformed in accordance with the relative displacement between printed wiring board 1 and semiconductor device 7 as shown in FIG. 9. This construction alleviates the stress that is applied to solder 9 and eliminates the danger that stress applied to solder 9 will cause breakage of solder 9, and therefore improves the reliability of solder 9. The improvement in the reliability of solder 9 enables an improvement in the reliability of the electrical connection between printed wiring board 1 and semiconductor device 7.

FIG. 9 shows a case in which electrode pad 4a is displaced in a direction of uplift from printed wiring board 1, but because electrode pad 4a is supported only by interconnect 3a in vacant space 6, displacement is also possible in the direction of pressure toward printed wiring board 1. Thus, even in a temperature environment in which low temperatures and high temperatures are alternately repeated, electrode pad 4a is displaced both in the direction of uplift from printed wiring board 1 and in the direction of pressure toward printed wiring board 1 in accordance with this temperature environment, and the stress that is applied to solder 9 can be effectively alleviated.

In the present embodiment, an example has been presented in which the connection member is solder 9, but materials other than solder such as gold, copper or conductive resin may also be used as the connection member.

Second Embodiment

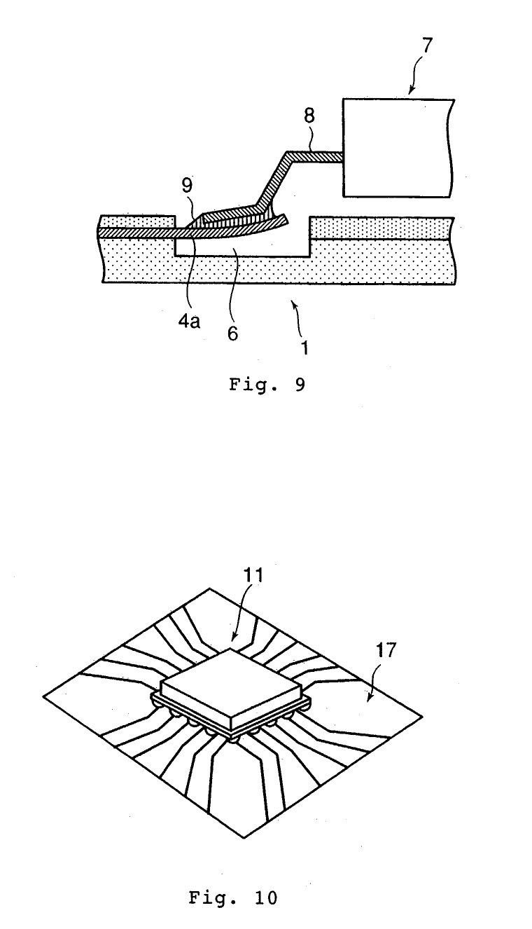

Referring now to FIGS. 10 and 11, semiconductor device 11 of the present embodiment is of the so-called “BGA type” and includes: semiconductor element 12 that is provided with electrode pad 12a; interconnect 14 provided on the lower surface of semiconductor device 11 and having both ends formed as electrode pads 14a and 14b; solder ball 13 that is provided on a part of electrode pad 14a of interconnect 14; wire 15 for electrically connecting electrode pad 14b and electrode pad 12a; and encapsulation resin 16. Encapsulation resin 16 encapsulates semiconductor element 12, a portion of interconnect 14, and wire 15. Vacant space 17 is formed in the region of encapsulation resin 16 that is in the vicinity of electrode pad 14a, and electrode pad 14a is provided in a form that is exposed in vacant space 17.

In semiconductor device 11 of the present embodiment, semiconductor device 11 itself is provided with the constituent elements that are referred to as the connection members in the present invention. In other words, solder ball 13 is the connection member for connecting semiconductor device 11 and electrode pad 19 of printed wiring board 18, and wire 15 is the connection member for connecting semiconductor element 12 and interconnect 14.

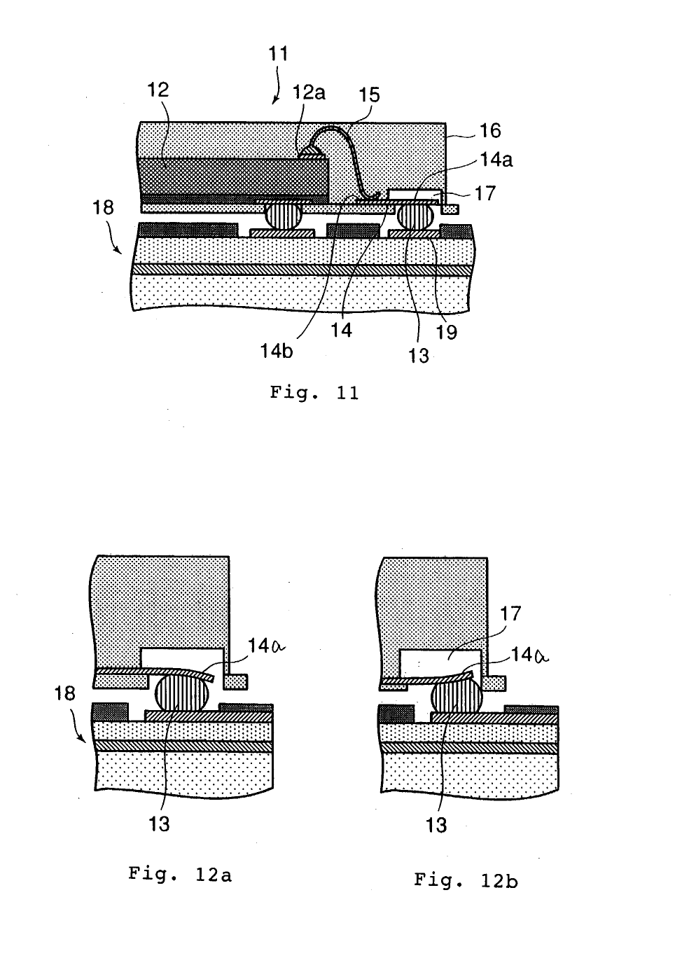

In semiconductor device 11 of the present embodiment as described in the foregoing explanation, electrode pad 14a that is provided with solder ball 13 is disposed extending into vacant space 17, and electrode pad 14a is therefore capable of being deformed in vacant space 17 when stress resulting from, for example, changes in the ambient temperature, acts to cause the relative displacement of semiconductor device 11 and printed wiring board 18. This configuration reduces the stress that is applied to solder ball 13 and thus enables an improvement of the reliability of the electrical connection provided by solder ball 13. As an example, in the event of deformation that causes semiconductor device 11 and printed wiring board 18 to move away from each other, electrode pad 14a is deformed toward printed wiring board 18 as shown in FIG. 12a, whereby the stress acting on solder ball 13 is alleviated. On the other hand, in the event of deformation such that semiconductor device 11 and printed wiring board 18 approach each other, electrode pad 14a is deformed by being pressed into vacant space 17 as shown in FIG. 12b, whereby the stress acting on solder ball 13 is again alleviated.

Although the present embodiment presents a case in which the connection member is solder ball 13, the present invention is not limited to this form, and gold, copper, or conductive resin may also be used as the connection member.

Third Embodiment

In the above-described embodiment, an example was shown in which, for electrode pads that are used for connection with the outside, a vacant space was provided for each individual electrode pad, and moreover, each entire electrode pad existed inside a vacant space. However, the vacant spaces in the present invention are not limited to this form. Explanation will be hereafter presented regarding a variety of other examples of the vacant space.

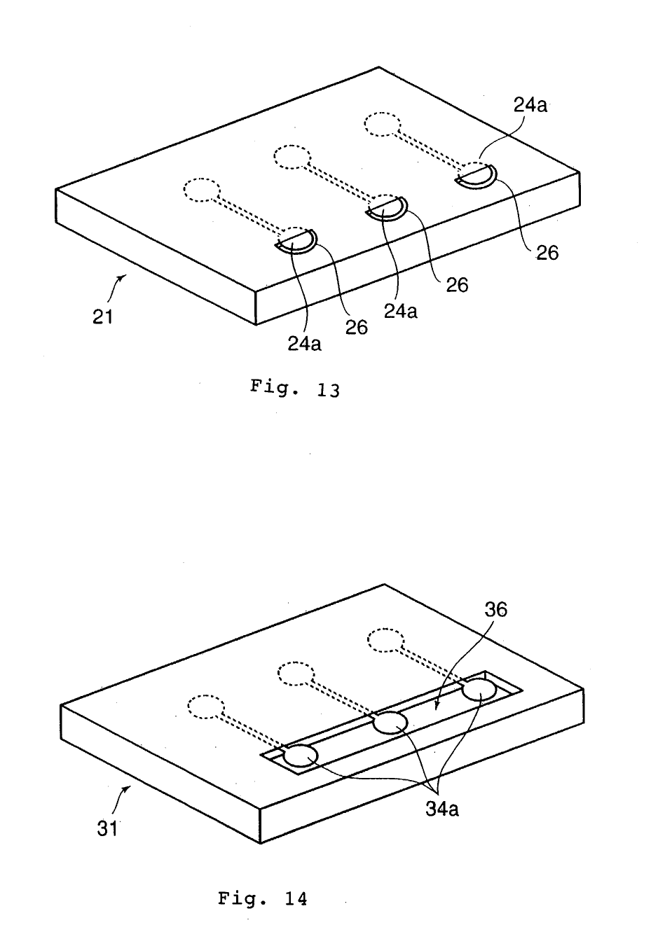

The example shown in FIG. 13 is an example of printed wiring board 21 in which respective vacant spaces 26 of the insulating layer are provided for each electrode pad 24a, but in which only a portion of each electrode pad 24a is located within vacant space 26. However, even when the insulating layer supports and closely adheres to a portion of the back surface of electrode pad 24a (the surface on the opposite side from the surface on which solder is provided when connecting components), the portion of electrode pad 24a that is positioned in vacant space 26 can still be deformed. This structure therefore enables alleviation of stress that is applied to the solder (connection member) that connects the component and electrode pad 24a after a component (not shown in the figure) is mounted on printed wiring board 21. In addition, the close adhesion of a portion of the back surface of electrode pad 24a to the insulating layer further restrains the degree to which electrode pad 24a can be depressed when a component is mounted on printed wiring board 21, and therefore improves the positional stability of electrode pad 24a.

FIG. 14 shows an example of printed wiring board 31 in which common vacant space 36 is provided in the insulating layer for a plurality of electrode pads 34a. This example simplifies the patterning of vacant space 36. This example can also reduce time and trouble when designing vacant space 36 because a vacant space need not be provided for each individual electrode pad 34a.

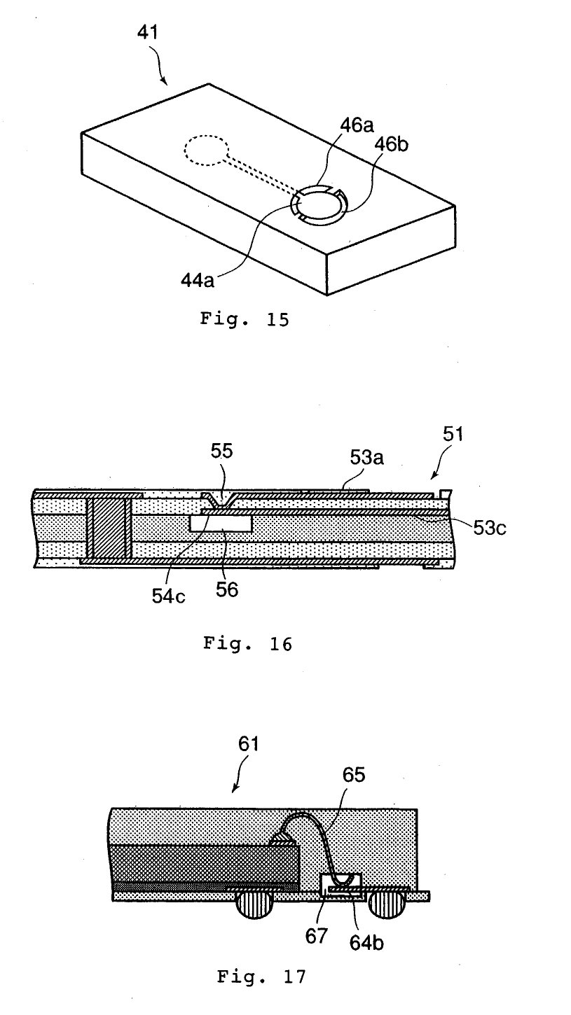

FIG. 15 shows an example of printed wiring board 41 in which a plurality of vacant spaces 46a and 46b are provided in the insulating layer for one electrode pad 44a, and the central portion of electrode pad 44a closely adheres to and is supported on the insulating layer. As with the example that is shown in FIG. 13, this case also enables an improvement of the positional stability of electrode pad 44a when a component is mounted on printed wiring board 41. In addition, no particular limitation is placed on the position and area of the portions of electrode pads 24a and 44a that closely adhere to the insulating layer in the examples shown in FIG. 13 and FIG. 15. However, since stress applied to a connection member is alleviated by the displacement of electrode pads 24a and 44a, the stress can be effectively alleviated by providing a vacant space such that electrode pads 24a and 44a are displaced at least in the portion at which a high level of stress tends to be applied.

Although a printed wiring board was taken as the example in FIGS. 13-15, this construction can also be applied for a semiconductor device. Further, any combination of the constructions shown in FIGS. 13-15 is possible.

The vacant space can be provided for electrodes inside a printed wiring board or semiconductor device. As an example, a vacant space 56 can be formed in an interlayer insulating layer at the position of via-hole 55 that connects upper-layer interconnect 53a and interlayer interconnect 53c, as with printed wiring board 51 shown in FIG. 16. As for the relation between upper-layer interconnect 53a and interlayer interconnect 53c, via-hole 55 is the connection member of interconnect 53a and 53c, and the portion of interconnect 53c that connects with via-hole 55 functions as electrode pad 54c. Here, the application of vacant space 56 for this electrode pad 54c enables an alleviation of stress that is applied to via-hole 55 and enables an improvement of the reliability of via-hole 55 when printed wiring board 51 itself is deformed.

Via-hole 55 fulfills the role of the connection member that connects interlayer interconnect 53c and upper-layer interconnect 53a, and in a broad sense, the portion of interconnect 53c that connects with via-hole 55 is an electrode pad. The provision of vacant space 56 in an interlayer insulating layer for an electrode pad inside this printed wiring board 51 facilitates the displacement of the electrode pad part of interconnect 53c as compared with other parts when stress is applied to printed wiring board 51. This displacement of the electrode pad part of interconnect 53c alleviates the stress that is applied upon via-hole 55, improves the reliability of via-hole 55, and consequently, improves the reliability of the electrical connection between upper-layer interconnect 53a and interlayer interconnect 53c.

When vacant spaces are provided in a printed wiring board and the printed wiring board is divided by an electrode pads into regions, one contain a connection member and the other does not, a vacant space is preferably provided in the region that does not contain a connection member in order to facilitate the displacement of the corresponding electrode pads. In other words, vacant space 56 is preferably provided in an interlayer insulating layer rather than an upper-layer insulating layer, as in the example shown in FIG. 16.

FIG. 17 shows an example of semiconductor device 61 that is provided with vacant space 67 in the vicinity of the connection part of electrode pad 64b and wire 65. In the example shown in FIG. 17, vacant space 67 is formed by eliminating a part of the base member of semiconductor device 61 and a portion of the encapsulation resin. In this case as well, electrode pad 64b is displaced inside vacant space 67 when stress is applied to the semiconductor device itself, whereby the stress that is applied to wire 65 can be alleviated. This construction therefore improves the reliability of wire 65 and consequently improves the reliability of the electrical connection between wire 65 and electrode pad 64.

Vacant spaces 56 and 67 shown in FIGS. 16 and 17 may have the shapes and arrangements shown in FIGS. 13 to 15, or may have any combination of these shapes and arrangements.

Fourth Embodiment

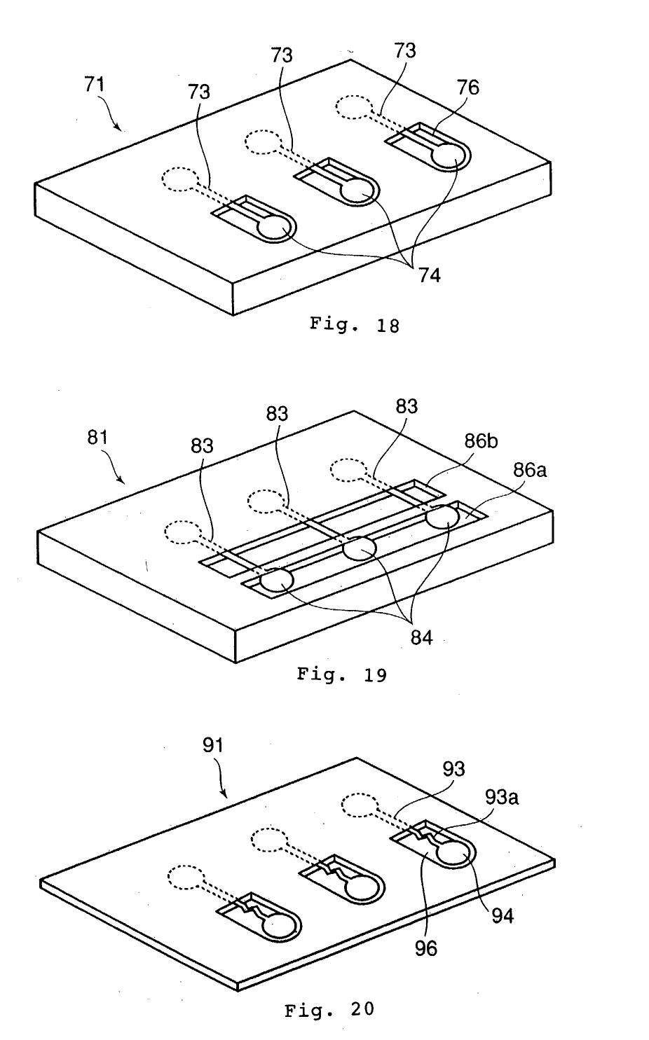

FIG. 18 shows an example of printed wiring board 71 according to the fourth embodiment of the present invention. In printed wiring board 71 of this embodiment, vacant spaces 76 are formed in an insulating layer so as to expose not only electrode pads 74 but also a part of interconnects 73 that connect to electrode pads 74. Exposing a portion of interconnects 73 in the vacant spaces allows electrode pads 74 to be displaced with a still greater degree of freedom and improves the reliability of connection members that are connected to electrode pads 74.

A modification of the present embodiment is shown in FIG. 19. In printed wiring board 81 that is shown in FIG. 19, first vacant space 86a corresponding to electrode pads 84 and second vacant space 86b corresponding to interconnects 83 are provided in an insulating layer, the border portion between interconnects 83 and electrode pads 84 being supported and in close contact with the insulating layer of printed wiring board 81. Compared to a case of providing only the electrode pads in a vacant space, this case of providing not only the electrode pads but also a portion of the interconnects in vacant spaces facilitates depression of the electrode pads when a component.is mounted. As with the example shown in FIG. 19, a construction in which the border portion between interconnects 83 and electrode pads 84 is supported can restrain the depression of electrode pads 84 when a component is mounted on printed wiring board 81. Although first vacant space 86a is provided in common to a plurality of electrode pads 84 in the example shown in FIG. 19, first vacant spaces 86a may also be individually provided for each electrode pad 84. A similar construction may be adopted for second vacant space 86b.

Although a printed wiring board was taken as the example in the present embodiment, a similar construction can be adopted for a semiconductor device. Regarding the shape and arrangement of the vacant spaces, the present embodiment further includes those constructions in which the shapes and arrangements that are shown in FIGS. 13 to 17 are applied when vacant spaces are formed at positions that contain portions of the interconnects.

When a vacant space is provided at a position that contains a portion of an interconnect as in the present embodiment, the vacant space need not be provided at a position that includes the border portion between the interconnect and the electrode pad. However, a vacant space that is continuous from the electrode pad to the interconnect is preferable for the purpose of increasing the amount of displacement of the electrode pad.

Fifth Embodiment

In printed wiring board 91 of the present embodiment, interconnects 93 that connect to electrode pads 94 include, at least in the vicinity of the border with electrode pads 94, surplus length portions 93a that are bent into a wave shape within a plane that is perpendicular to the main plane of printed wiring board 91, as shown in FIG. 20 and FIG. 21. Vacant spaces 96 are formed in the regions of the insulating layer that contain electrode pads 94 and surplus length portions 93a of interconnects 93. This provision of surplus length portions 93a in interconnects 93 greatly eases the limits on the amount of displacement and limits on the direction of displacement of electrode pads 94 when compared to a case in which interconnects 93 have a linear form, and facilitates displacement of electrode pads 94. The adoption of this form can further alleviate the stress that is applied to the connection member (solder) for connecting the component and electrode pads 94 after a component has been mounted on printed wiring board 91, and can effectively improve the reliability of the connection member, and consequently, the reliability of the electrical connection between the component and electrode pads 94.

In FIGS. 20 and 21, an example was shown in which interconnects 93 include surplus length portions 93a that are bent within a plane that is perpendicular to the main plane of printed wiring board 91, but the shape of the interconnects in the present embodiment is not limited to this form.

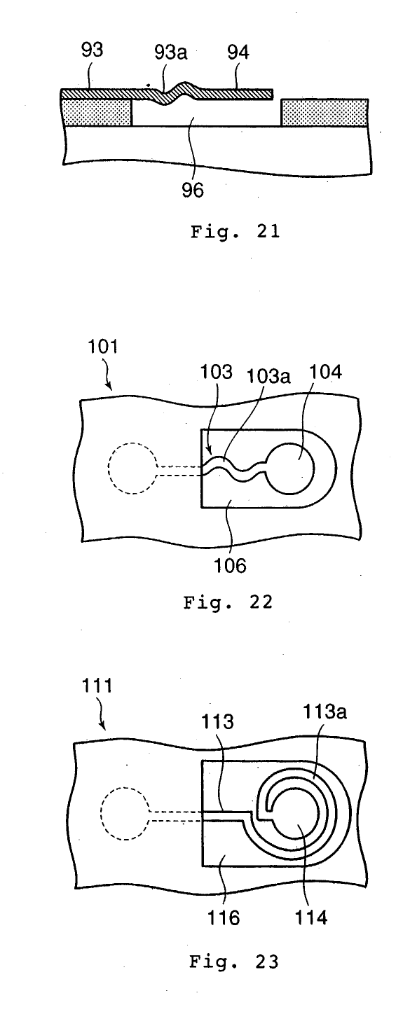

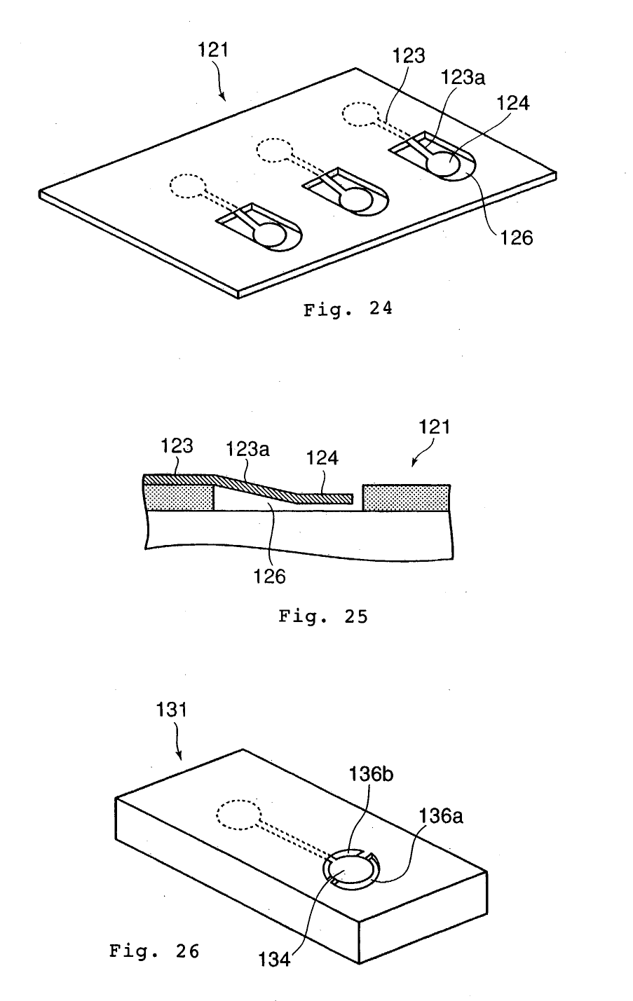

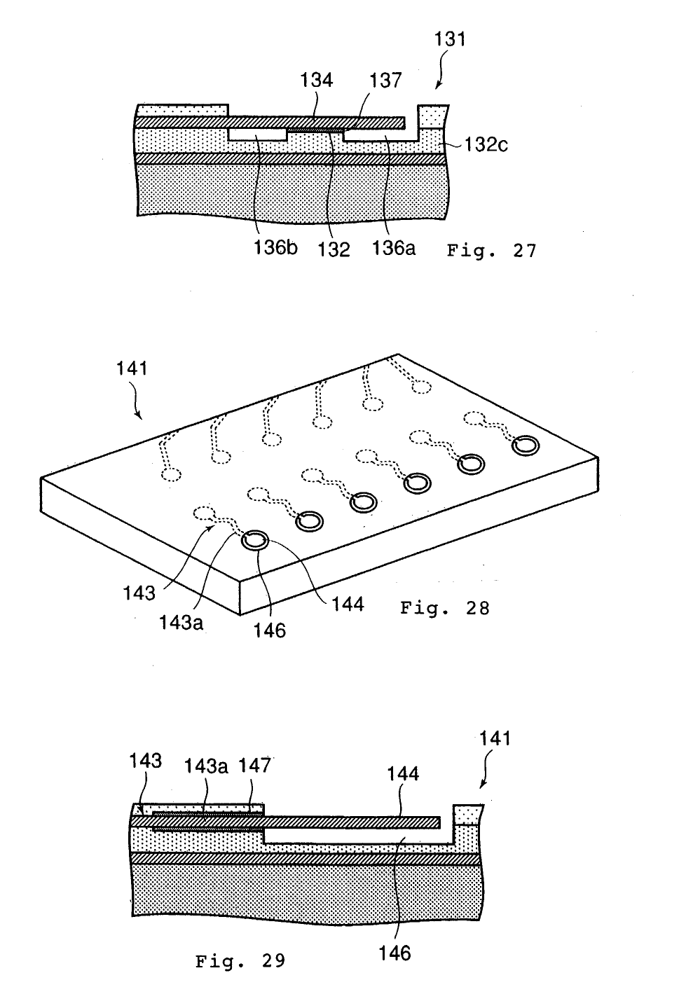

In printed wiring board 101 that is shown in FIG. 22, for example, interconnect 103 that is connected to electrode pad 104 includes, within the region in which vacant space 106 is provided and in a portion of interconnect 103 that is close to electrode pad 104, surplus length portion 103a that curves within a plane that is parallel to the main plane of printed wiring board 101. In printed wiring board 111 that is shown in FIG. 23, interconnect 113 includes, within the region in which vacant space 116 is provided and in a part of interconnect 113 that is close to electrode pad 114, surplus length portion 113a that curves around the circumference of electrode pad 114 and then connects to electrode pad 114. In printed wiring board 121 that is shown in FIG. 24 and FIG. 25, which is a sectional view of FIG. 24, electrode pads 124 are formed at positions that are shifted into vacant spaces 126 with respect to the plane in which interconnects 123 are formed, whereby surplus length portions 123a are the parts of the interconnects that are in the regions in which vacant spaces 126 are provided. The constructions that are shown in FIGS. 20-25 may also be combined as appropriate.

Although various shapes have been shown for the surplus length portion that is provided in the interconnect, when the process of forming an actual interconnect is considered, it is preferable to provide surplus length portions 103a and 113a within a plane that is parallel to the main planes of printed wiring boards 101 and 111 as shown in FIG. 22 or FIG. 23 is preferable because interconnects 103 and 113 are easier to form. In particular, a construction that includes surplus length portion 113a that winds around the circumference of electrode pad 114 as shown in FIG. 23 is effective when interconnect 113 is short and there is no room for providing a surplus length portion in the middle of interconnect 113 (for example, when a via-hole is in immediate proximity to electrode pads 114).

Although examples having surplus length portions in regions in which vacant spaces were provided were shown in each of the above-described modifications of the present embodiment, the present embodiment is not limited to these forms, as will be explained hereinbelow. Nevertheless, a surplus length portion is preferably provided inside a vacant space in order to enable a greater degree of displacement of the electrode pad. Further, although an example of a printed wiring board was presented in the present embodiment, each of the above-described examples can also be applied to a semiconductor device.

Sixth Embodiment

Although the portions of the electrodes and interconnects that are not exposed in vacant spaces are secured by adjacent parts in each of the above-described embodiments, the portions that are not exposed in the vacant spaces can also be constructions capable of displacement.

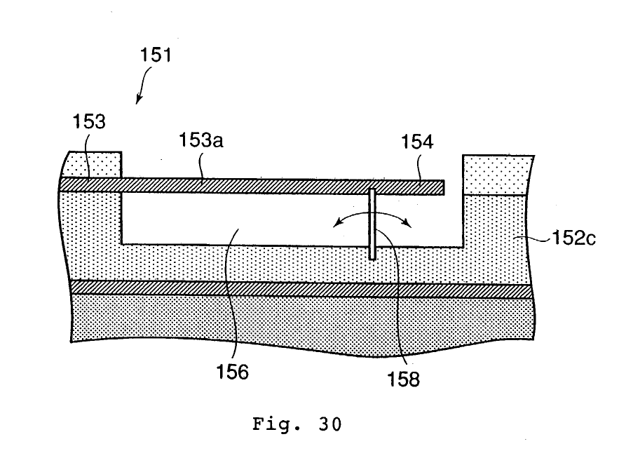

FIG. 26 is a perspective view showing a printed wiring board that is an example of such a construction, and FIG. 27 is a sectional view taken along the interconnect of FIG. 26.

As with the construction that is shown in FIG. 15, printed wiring board 131 shown in FIG. 26 and FIG. 27, electrode pad 134 is formed straddling two vacant spaces 136a and 136b that are provided in insulating layer 132c, the central portion of electrode pad 134 being supported by support 132, which is the region between two vacant spaces 136a and 136b of the insulating layer. However, the printed wiring board 131 shown in FIG. 26 and FIG. 27 differs from printed wiring board 41 shown in FIG. 15 in that the portion of electrode pad 134 that is supported by printed wiring board 131 is not secured to printed wiring board 131, but rather, simply contacts printed wiring board 131.

The adoption of this construction not only avoids depression of electrode pad 134 when a component is mounted, but in addition, allows greater displacement in the direction away from printed wiring board 131 than is possible in the construction shown in FIG. 15 because the entirety of electrode pad 134 can be displaced rather than only the portions of electrode pad 134 in vacant spaces 136a and 136b.

In a construction in which electrode pad 134 is merely supported by support 132, however, electrode pad 134 is incapable of displacement in the direction of depression toward printed wiring board 131. However, a construction may be adopted in which low elastic member 137 is provided on the upper surface of support 132 as shown in FIG. 27, and electrode pad 134 is supported by way of this low elastic member 137. No particular limitation is placed on the composition of low elastic member 137 as long as it is capable of elastic deformation when force acts to press electrode pad 134 down, but a material may be used such as resin that has an elastic modulus that is lower than support 132. This construction allows the entirety of electrode pad 134 to undergo displacement in the direction of depression toward printed wiring board 131 after a component has been mounted on printed wiring board 131, thereby enabling a greater improvement of the reliability of the connection member that connects the component and electrode pad 134. In addition, a construction may be adopted in which, instead of providing low elastic member 137, the height of support 132 is reduced such that a gap is formed between support 132 and electrode pad 134, thereby enabling the entirety of electrode pad 134 to be displaced in the direction of depression toward printed wiring board 131.

FIG. 28 shows a modification of the present embodiment, and FIG. 29 shows a sectional view showing the vacant space portion of this modification. In printed wiring board 141 shown in FIGS. 28 and 29, surplus length portions 143a that are similar to those of FIG. 22 are provided in interconnects 143 that connect to electrode pads 144. Vacant spaces 146 are formed only in positions in insulating layer that correspond to electrode pads 144, and the surplus length portions 143a of interconnects 143 are not exposed in vacant spaces 146 but kept inside printed wiring board 141. However, the vicinities of surplus length portions 143a of interconnects 143 are covered by low elastic members 147.

By adopting this form, not only electrode pad 147 but the surplus length portion 143a of interconnect 143 as well is capable of displacement within the range of elastic deformation of low elastic member 147. The amount of displacement of electrode pad 144 can therefore be made greater than that of the construction that is shown in FIG. 5, whereby a corresponding improvement in the reliability of the connection member can be obtained. In addition, in the construction shown in FIGS. 28 and 29, interconnect 143 is not exposed and is protected by surrounding material, whereby the reliability of interconnect 143 itself can be improved. Although no particular limitation is placed on the regions in which interconnect 143 is covered by low elastic member, low elastic member 147 is preferably provided so as to connect with vacant space 146 to increase the degree to which electrode pad 144 can be displaced.

Although a construction has been shown in which surplus length portion 143a of interconnect 143 is covered by low elastic member 147 to increase the degree to which electrode pad 144 can be displaced, a gap may be provided between surplus length portion 143a and the material that surrounds surplus length portion 143a instead of covering surplus length portion 143a with low elastic member 147, whereby surplus length portion 143a is capable of displacement within the range of this gap. Further, although explanation has been presented for a case in which interconnect 143 includes surplus length portion 143a, a similar construction in which interconnect 143 is linear and lacks a surplus length portion may also be applied. Further, as an additional construction to the construction shown in FIGS. 28 and 29, a support such as shown in FIG. 27 can be provided on the back surface of electrode pad 144. Finally, although only electrode pads 144 are exposed in vacant spaces 146 in the example shown in FIGS. 28 and 29, a construction is also possible in which the portions of interconnects 143 that are in the vicinity of electrode pads 144 are exposed. In this case as well, the portions of interconnects 143 that are not exposed in vacant spaces 146 are covered by low elastic members 147, but a support may also be provided on the back surfaces of electrode pads 144.

Although a printed wiring board has been taken as the example in the explanation of an embodiment that allows displacement of the portions of the electrode pads and the portions of the interconnects that are not exposed in vacant spaces, the construction of the present embodiment can also be similarly applied to a semiconductor device instead of a printed wiring board.

Seventh Embodiment

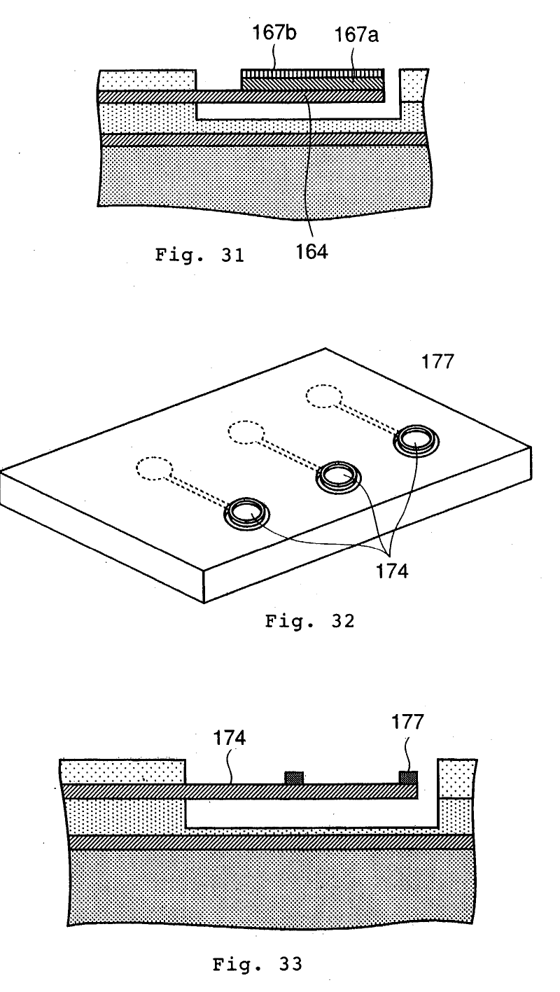

As shown in FIG. 30, interconnect 153 in the present embodiment has surplus length portion 153a that is close to the border between interconnect 153 and electrode pad 154; and vacant space 156 is formed in the insulating layer of printed wiring board 151 to expose electrode pad 154 and surplus length portion 153a of interconnect 153. Pin member 158 for supporting electrode pad 154 is provided so as to protrude from vacant space 156 in insulating layer 152c at a position that corresponds to electrode pad 154. The lower end of pin member 158 is supported in insulating layer 152c such that pin member 158 can sway freely, and the upper end of pin member 158 is secured in electrode pad 154. This support of electrode pad 154 by means of pin member 158 allows electrode pad 154 to undergo displacement while causing pin member 158 to sway.

Thus, when stress is applied to the connection member that connects a component and electrode pad 154 after a component has been mounted on printed wiring board 151, electrode pad 154 is displaced according to this stress and thus allow alleviation of the stress that is applied to the connection member. Moreover, the support of electrode pad 154 by pin member 158 can prevent the depression of electrode pad 154 when a component is mounted on printed wiring board 151.

Although an example has been presented in FIG. 30 in which pin member 158 is supported in a manner that allows pin member 158 to sway freely, the same effect can be obtained by a construction in which a pin member that is capable of elastic deformation is fixedly provided in insulating layer 152c and electrode pad 154 is supported in a manner that allows displacement through the elastic deformation of the pin member. In this case, the pin member need not be secured to the electrode pad. In addition, a construction that allows displacement of the electrode pad by means of a pin member as in the present embodiment can be applied to a semiconductor device as well as to a printed wiring board.

Eighth Embodiment

In the present embodiment, various examples are presented of the construction of an electrode pad. As long as no particular limitation is placed on the elements of the construction other than the electrode pad, the examples shown below can be applied to each of the above-described embodiments. In addition, although a printed wiring board is taken as the example in the following explanation, the construction of the present embodiment can also be applied to a semiconductor device.

In the example that is shown in FIG. 31, two types of conductive materials 167a and 167b (for example, nickel and gold) are laminated on the surface of electrode pad 164 as a barrier metal. This provision of a barrier metal on the surface of electrode pad 164 prevents the heat of the solder, which is the connection member, from melting electrode pad 164 when a component is connected to electrode pad 164, and an improvement of the reliability of the interface between electrode pad 164 and the solder can therefore be obtained.

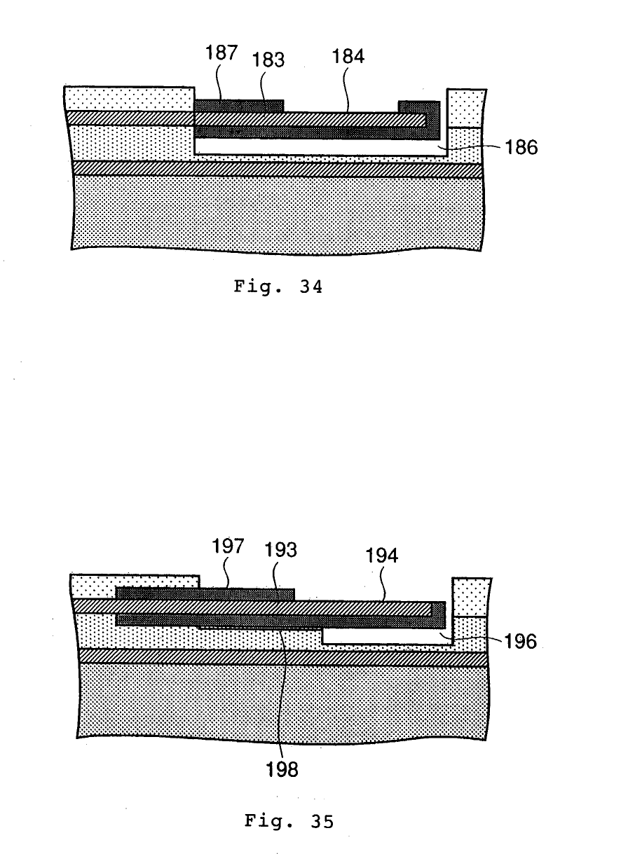

In the example that is shown in FIG. 32 and in FIG. 33, which is a sectional view taken along the interconnect, insulating material 177 is provided along the perimeter of the surface of electrode pad 174. By providing this insulating material 177, insulating material 177 functions as a wall for preventing the outflow of solder when connecting a component to electrode pads 174.

In the example shown in FIG. 34, vacant space 186 is provided such that electrode pad 184 and a portion of interconnect 183 that connects to this electrode pad 184 are exposed. Insulating layer material 187 is then provided over the entire surface of the portion of interconnect 183 and electrode pad 184 that is exposed in vacant space 186 except for the portion in which solder is provided when a component is connected. This provision of insulating material 187 protects interconnect 183 and electrode pad 184, prevents direct contact with the outside air, and improves the reliability of interconnect 183 and electrode pad 184 themselves.

In the example shown in FIG. 35, as with the example of FIG. 34, insulating material 197 is provided on interconnect 193 and electrode pad 194 to protect portions of interconnect 193 and electrode pad 194 that are not needed for connection with a component. In the example shown in FIG. 35, however, only electrode pad 194 is exposed in vacant space 196 and insulating material 197 is also provided on portions that are not exposed in vacant space 196. Further, insulating material 197 only contacts insulating layer at the end of interconnect 193 on the electrode pad 194 side, and this portion of interconnect 193 is capable of displacement.

A barrier metal that is provided on the surface of electrode pads, a wall for preventing outflow of solder, and a construction for protecting interconnects and electrode pads have been described in the foregoing explanation as additional constructions that are provided on electrode pads and interconnects. These constructions may each be used alone or in combination according to necessity.

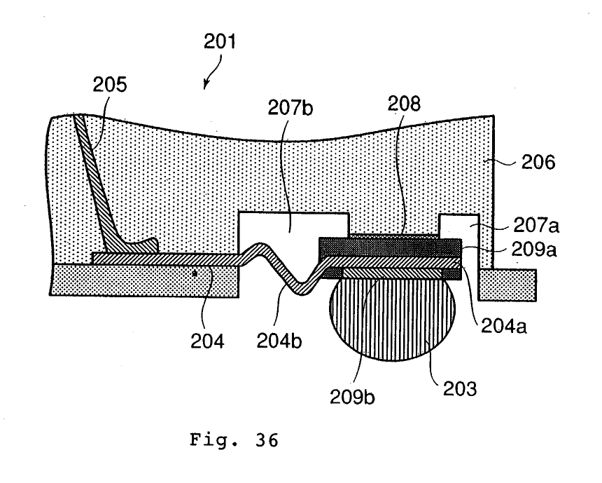

FIG. 36 shows an example in which several constructions that are representative of each of the above-described embodiments have been applied to an electrode pad that is connected to solder balls of a semiconductor device.

The semiconductor device shown in FIG. 36 includes: solder ball 203 for mounting onto printed wiring board (not shown in the figure); interconnect 204 in which electrode pad 204a for connecting to solder ball 203 is provided on one end; a wire for connecting interconnect 204 and a semiconductor element (not shown in the figure); and encapsulation resin 206 for encapsulating elements such as the semiconductor element. Two vacant spaces 207a and 207b are formed in encapsulation resin 206. One vacant space 207a is formed at a position that corresponds to the tip of electrode pad 204a. The other vacant space 207b is formed at a position that includes the root of electrode pad 204a and a portion of interconnect 204 that is linked to this root of electrode pad 204a. The central portion of electrode pad 204a is supported by mere contact at support 208, which is the region between the two vacant spaces 207a and 207b of encapsulation resin 206. Conductive material 209b is provided on electrode pad 204a as a barrier metal in the region in which solder ball 203 is provided, and insulative material 209a is provided on the remaining regions of electrode pad 204a to avoid space unnecessary exposure of electrode pad 204a. Finally, surplus length portion 204b is formed in the portion of interconnect 204 that is exposed in vacant space 207b.

Although certain preferred embodiments of the present invention have been shown and described in detail, it should be understood that various changes and modifications may be made without departing from the spirit or scope of the appended claims.

What is claimed is:

1. A printed wiring board, comprising:
an insulating layer; and
an electrode pad and an interconnect connected to said electrode pad that are provided on said insulating layer;
wherein a vacant space is formed in said insulating layer, and of said electrode pad and said interconnect, at least a portion of the electrode pad is exposed in said vacant space.

2. A printed wiring board according to claim 1, wherein only said electrode pad is exposed in said vacant space.

3. A printed wiring board according to claim 2, wherein a portion of said interconnect that is close to said electrode pad is covered by a low elastic member.

4. A printed wiring board according to claim 3, wherein said a portion of said interconnect that is close to said electrode pad is in a bent shape.

5. A printed wiring board according to claim 2, further comprising a support for supporting a portion of the back surface of said electrode pad.

6. A printed wiring board according to claim 5, wherein said support supports said electrode pad such that said electrode pad can be displaced.

7. A printed wiring board according to claim 1, wherein said electrode pad and a portion of said interconnect that is close to said electrode pad are exposed in said vacant space.

8. A printed wiring board according to claim 7, wherein a portion of said interconnect that is not exposed in said vacant space is covered by a low elastic member.

9. A printed wiring board according to claim 7, wherein a portion of said interconnect that is close to said electrode pad is in a bent shape.

10. A printed wiring board according to claim 7, further comprising a support for supporting said electrode pad and a portion of the back surface of said interconnect that is exposed in said vacant space.

11. A printed wiring board according to claim 10, wherein said support supports said electrode pad and the portion of said interconnect that are exposed in said vacant space such that said electrode pad and said interconnect are capable of displacement.

12. A semiconductor device, comprising:
a semiconductor element;
encapsulation resin for encapsulating said semiconductor element; and
an interconnect that is connected to said semiconductor element and an electrode pad that is connected to said interconnect;
wherein a vacant space is formed in said encapsulation resin and wherein, of said electrode pad and said interconnect, at least a portion of said electrode pad is exposed in said vacant space.

13. A semiconductor device according to claim 12, wherein only said electrode pad is exposed in said vacant space.

14. A semiconductor device according to claim 13, wherein a portion of said interconnect that is close to said electrode pad is covered by a low elastic member.

15. A semiconductor device according to claim 14, wherein a portion of said interconnect that is close to said electrode pad is in a bent shape.

16. A semiconductor device according to claim 13, further comprising a support for supporting a portion of the back surface of said electrode pad.

17. A semiconductor device according to claim 16, wherein said support supports said electrode pad such that said electrode pad can be displaced.

18. A semiconductor device according to claim 12, wherein said electrode pad and a portion of said interconnect that is close to said electrode pad are exposed in said vacant space.

19. A semiconductor device according to claim 18, wherein a portion of said interconnect that is not exposed in said vacant space is covered by a low elastic member.

20. A semiconductor device according to claim 18, wherein a portion of said interconnect that is close to said electrode pad is in a bent shape.

21. A semiconductor device according to claim 18, further comprising a support for supporting said electrode pad and a portion of the back surface of said interconnect that are exposed in said vacant space.

22. A semiconductor device according to claim 21, wherein said support supports displaceably said electrode pad and a portion of said interconnect that is exposed in said vacant space.

23. An electrical connection structure, comprising:
a printed wiring board comprising an insulating layer, and an electrode pad and an interconnect that is connected to said electrode pad that are provided on said insulating layer; wherein a vacant space is formed in said insulating layer, and of said electrode pad and said interconnect, at least a portion of said electrode pad is exposed in said vacant space; and
a component that is electrically connected to said electrode pad by a connection member.

24. An electrical connection structure according to claim 23, wherein said connection member is solder, gold, copper, or a conductive resin.

25. An electrical connection structure, comprising:
a semiconductor device comprising a semiconductor element, an encapsulation resin for encapsulating said semiconductor element, an interconnect that is connected to said semiconductor element, and an electrode pad that is connected to said interconnect; wherein a vacant space is formed in said encapsulation resin; and, of said electrode pad and said interconnect, at least a portion of said electrode pad is exposed in said vacant space; and
a printed wiring board, the surface of which is provided with an electrode pad that is electrically connected to an electrode pad of said semiconductor device;
wherein the electrode pad of said semiconductor device and the electrode pad of said printed wiring board are electrically connected by means of a connection member.

26. An electrical connection structure according to claim 25, wherein:
said semiconductor device is a semiconductor device of the ball grid array type, and
said connection member is solder, gold, copper, or a conductive resin that is provided on the electrode pad of said semiconductor device.
